(19) United States
(12) Patent Application Publication
(10) Pub. No.: US 2025/0194128 A1
(43) Pub. Date: Jun. 12, 2025

(54) SEMICONDUCTOR DEVICE AND FABRICATION METHOD THEREOF

(71) Applicant: INDUSTRIAL TECHNOLOGY RESEARCH INSTITUTE, Hsinchu (TW)

(72) Inventors: Po-Tsung TU, Tainan City (TW); Hsiang-Chun WANG, Taoyuan City (TW); Jui-Chin CHEN, Zhubei City (TW); Chang-Yan HSIEH, Yilan County (TW); Hui-Yu CHEN, Taichung City (TW); Po-Chun YEH, Taichung City (TW); Hao-Chung KUO, Hsinchu (TW)

(73) Assignee: INDUSTRIAL TECHNOLOGY RESEARCH INSTITUTE, Hsinchu (TW)

(21) Appl. No.: 18/396,323

(22) Filed: Dec. 26, 2023

(30) Foreign Application Priority Data
Dec. 8, 2023 (TW) 112147897

(51) Int. Cl. H01L 29/66; H01L 29/20; H01L 29/417; H01L 29/778

(52) U.S. Cl. CPC H10D 30/015; H10D 30/475; H10D 62/8503; H10D 64/251

(57) ABSTRACT

The disclosure provides a semiconductor device and a fabrication method thereof and the fabrication method includes following steps: forming a semiconductor stack on a substrate; forming a N type doping layer on the semiconductor stack; patterning the N type doping layer by electron beam lithography to form a source N type doping part and a drain N type doping part; forming a source electrode on the source N type doping part; forming a drain electrode on the drain N type doping part; and forming a gate electrode that is located between the source N type doping part and the drain N type doping part on the semiconductor stack.

### CROSS-REFERENCE TO RELATED APPLICATIONS

All related applications are incorporated by reference. The present application is based on, and claims priority from, Taiwan (International) Application Serial Number 112147897 filed on Dec. 8, 2023, the disclosure of which is hereby incorporated by reference herein in its entirety.

### TECHNICAL FIELD

The disclosure relates to a semiconductor device and a fabrication method thereof.

### BACKGROUND

Due to the advantages of low on-resistance, high current density and high breakdown voltage, AlGaN/GaN High Electron Mobility Transistor (HEMT) are widely used for applications related to high-power electronic components. The polarization of the GaN makes the AlGaN/GaN heterostructure form 2D electron gases (2DEG) near a heterojunction, which allows the AlGaN/GaN HEMT to operate under high current.

### SUMMARY

One embodiment of this disclosure provides a fabrication method of a semiconductor device including following steps: forming a semiconductor stack on a substrate; forming a N type doping layer on the semiconductor stack; patterning the N type doping layer by electron beam lithography to form a source N type doping part and a drain N type doping part; forming a source electrode on the source N type doping part; forming a drain electrode on the drain N type doping part; and forming a gate electrode that is located between the source N type doping part and the drain N type doping part on the semiconductor stack.

Another embodiment of this disclosure provides a semiconductor device including a substrate, a semiconductor stack, a source N type doping part, a drain N type doping part, a source electrode, a drain electrode and a gate electrode. The semiconductor stack is formed on the substrate. The source N type doping part is formed on the semiconductor stack. The drain N type doping part is formed on the semiconductor stack. The source electrode is formed on the source N type doping part. The drain electrode is formed on the drain N type doping part. The gate electrode is formed on the semiconductor stack and located between the source N type doping part and the drain N type doping part. A gap width between the source N type doping part and the drain N type doping part is at least ten times larger than a width of the gate electrode.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a schematic view of a semiconductor device according to a first embodiment of the disclosure;

FIG. 2 to FIG. 10 are schematic views showing a fabrication method of the semiconductor device in FIG. 1;

FIG. 11 is a schematic view of a semiconductor device according to a second embodiment of the disclosure;

FIG. 12 is a cross-sectional view of the semiconductor device in FIG. 11 taken along line 12-12;

FIG. 13 is a cross-sectional view of a semiconductor device according to another embodiment of the disclosure; and

FIG. 14 is a cross-sectional view of a semiconductor device according to still another embodiment of the disclosure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

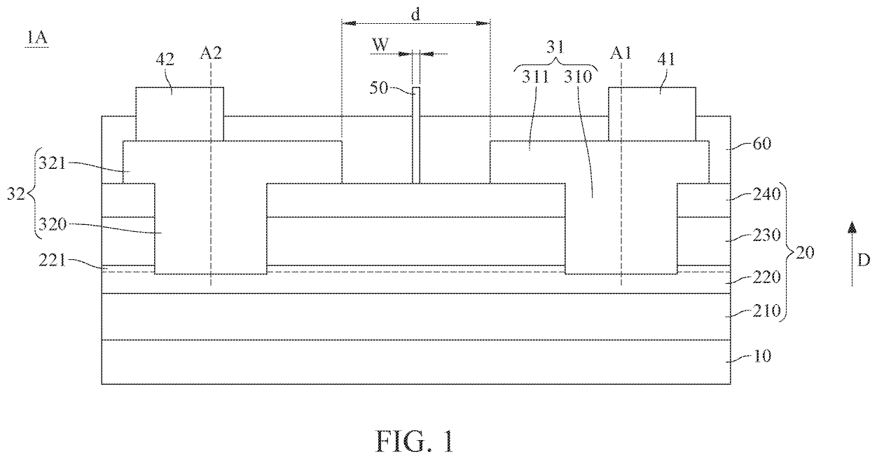

Please refer to FIG. 1 that is a schematic view of a semiconductor device 1A according to a first embodiment of the disclosure. In this embodiment, the semiconductor device 1A includes a substrate 10, a semiconductor stack 20, a source N type doping part 31, a drain N type doping part 32, a source electrode 41, a drain electrode 42 and a gate electrode 50.

The substrate 10 may include silicon, sapphire, any suitable crystalline material or any combination thereof. In some embodiments where the semiconductor stack 20 includes one or more III-V group compounds, the substrate 10 may be a semiconductor wafer.

The semiconductor stack 20 is formed on the substrate 10. In this embodiment, the semiconductor stack 20 may include a buffer layer 210, a channel layer 220, a barrier layer 230 and a cap layer 240. Further, the buffer layer 210, the channel layer 220, the barrier layer 230 and the cap layer 240 are sequentially stacked on the substrate 10 along a stacking direction D. Specifically, the buffer layer 210 is formed on the substrate 10. The channel layer 220 is formed on the buffer layer 210. The barrier layer 230 is formed on the channel layer 220, and the channel layer 220 is in contact with the barrier layer 230 on the heterojunction. The cap layer 240 is formed on the barrier layer 230. The channel layer 220 may have 2D electron gases 221 located adjacent to the barrier layer 230.

In this embodiment, the semiconductor device 1A may be a High Electron Mobility Transistor (HEMT). Further, the semiconductor device 1A may be a gallium nitride (GaN) heterostructure field-effect transistor. Specifically, the channel layer 220 and the cap layer 240 may include GaN, and the barrier layer 230 may include at least one of aluminum nitride (AlN), aluminum gallium nitride (AlGaN) and indium aluminum nitride (InAlN).

The source N type doping part 31 and the drain N type doping part 32 are formed on the semiconductor stack 20. In detail, the source N type doping part 31 may be disposed to correspond to a source region of the semiconductor device 1A, and the drain N type doping part 32 may be disposed to correspond to a drain region of the semiconductor device 1A. Further, both of the source N type doping part 31 and the drain N type doping part 32 may be N type GaN doping layers. Specifically, a doping concentration of the said N type GaN doping layer may be at least 1×10¹⁹. In this embodiment, the source N type doping part 31 includes one leg part 310 extending from the cap layer 240 to the channel layer 220. The leg part 310 may not penetrate through the channel layer 220, but may penetrate through the 2D electron gases 221. In addition, in this embodiment, the drain N type doping part 32 includes one leg part 320 extending from the cap layer 240 to the channel layer 220. The leg part 320 may not penetrate through the channel layer 220, but may penetrate through the 2D electron gases 221.

The source electrode 41 is formed on the source N type doping part 31, and the drain electrode 42 is formed on the drain N type doping part 32. In detail, both of the source electrode 41 and the drain electrode 42 may be ohmic contacts. Further, both of the source electrode 41 and the drain electrode 42 may include titanium, aluminum, nickel, gold, any other suitable metal materials or any combination thereof. In some embodiments, the source electrode 41 and/or the drain electrode 42 may have a stack structure including multiple metal layers.

The gate electrode 50 is formed on the semiconductor stack 20, and the gate electrode 50 is located between the source N type doping part 31 and the drain N type doping part 32 in a lateral direction perpendicular to the stacking direction D. During the operation of the semiconductor device 1A, the gate electrode 50 selectively provides a bias voltage to generate an electric field, thereby affecting the continuity of the 2D electron gases 221 extending from the source N type doping part 31 to the drain N type doping part 32. For example, when a bias voltage smaller than a threshold voltage is applied to the gate electrode 50, the gate electrode 50 may generate the electric field to close the continuity of the 2D electron gases 221.

In this embodiment, the source N type doping part 31 further comprises a head part 311 connected to the leg part 310, and a central axis (not shown) of the head part 311 is located closer to the gate electrode 50 than a central axis A1 of the leg part 310. As shown in FIG. 1, more than a half of the head part 311 is located on left part of the source N type doping part 31. In addition, the drain N type doping part 32 further comprises a head part 321 connected to the leg part 320, and a central axis (not shown) of the head part 321 is located closer to the gate electrode 50 than a central axis A2 of the leg part 320. As shown in FIG. 1, more than a half of the head part 321 is located on right part of the drain N type doping part 32.

In this embodiment, the semiconductor device 1A further comprises a protective layer 60 formed on the semiconductor stack 20. The protective layer 60 covers the source N type doping part 31 and the drain N type doping part 32, and the source electrode 41, the drain electrode 42 and the gate electrode 50 protrude out of the protective layer 60. The protective layer 60 may be formed by silicon oxide or silicon nitride.

In this embodiment, a gap width d between the source N type doping part 31 and the drain N type doping part 32 is at least ten times larger than a width W of the gate electrode 50. As shown in FIG. 1, the gap width d between the head part 311 of the source N type doping part 31 and the head part 321 of the drain N type doping part 32 may range from 100.0 nanometers (nm) to 200.0 nm, and the width W of the gate electrode 50 (may also be referred as gate length) may range from 10.0 nm to 20.0 nm.

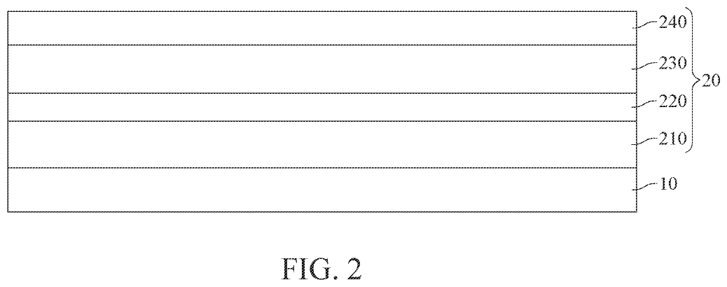

A fabrication method of the semiconductor device 1A will be described hereinafter. FIG. 2 to FIG. 10 are schematic views showing the fabrication method of the semiconductor device 1A in FIG. 1. As shown in FIG. 2, the semiconductor stack 20 is formed on the substrate 10, The semiconductor stack 20 includes the buffer layer 210, the channel layer 220, the barrier layer 230 and the cap layer 240 that are sequentially stacked. In this embodiment, the semiconductor stack 20 may be grown on the substrate 10 by an epitaxial process. The barrier layer 230 may be a single layer structure of aluminum gallium nitride, or may be a double-layer structure consist of an aluminum gallium nitride layer and an aluminum nitride layer.

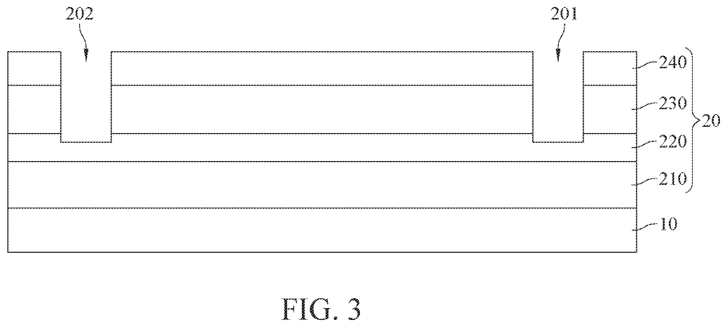

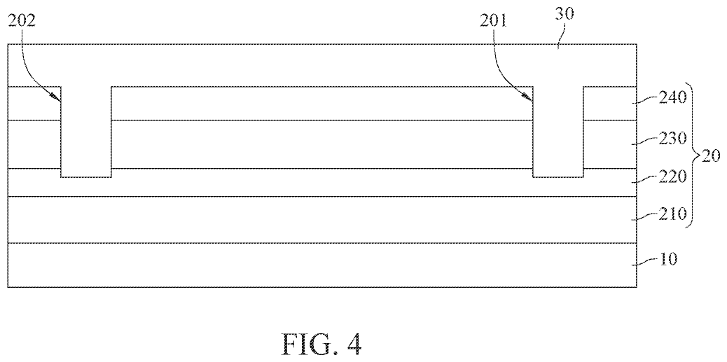

Then, a N type doping layer 30 is formed on the semiconductor stack 20. As shown in FIG. 3, a source cavity 201 and a drain cavity 202 are formed in the semiconductor stack 20. The source cavity 201 and the drain cavity 202 both penetrate through the barrier layer 230 and the cap layer 240, and do not penetrate through the channel layer 220. As shown in FIG. 4, the N type doping layer 30 is formed in the source cavity 201 and the drain cavity 202, and is formed on the cap layer 240. The N type doping layer 30 may be a N type gallium nitride doping layer. In this embodiment, a part of the semiconductor stack 20 may be removed by a dry etching process to form the source cavity 201 and the drain cavity 202, and the N type doping layer 30 may be grown by an epitaxial process. The N type doping layer 30 may be in direct contact with the cap layer 240 of the semiconductor stack 20.

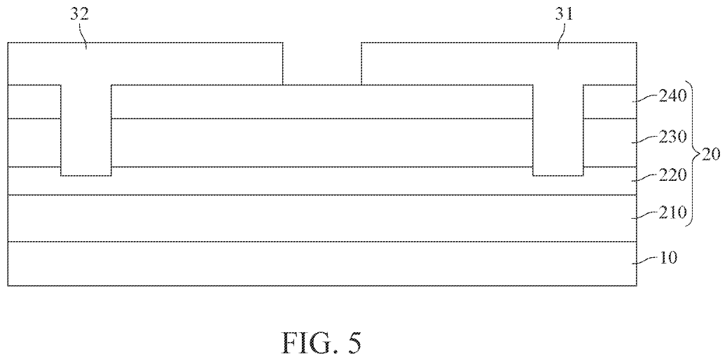

As shown in FIG. 5, the source N type doping part 31 and the drain N type doping part 32 are formed by patterning the N type doping layer 30 by electron beam lithography. In more detail, the source N type doping part 31 and the drain N type doping part 32 are formed by removing a part of the N type doping layer 30 that corresponds to a region between the source region and the drain region by using the electron beam. The source N type doping part 31 and the drain N type doping part 32 both may be in direct contact with the cap layer 240 of the semiconductor stack 20.

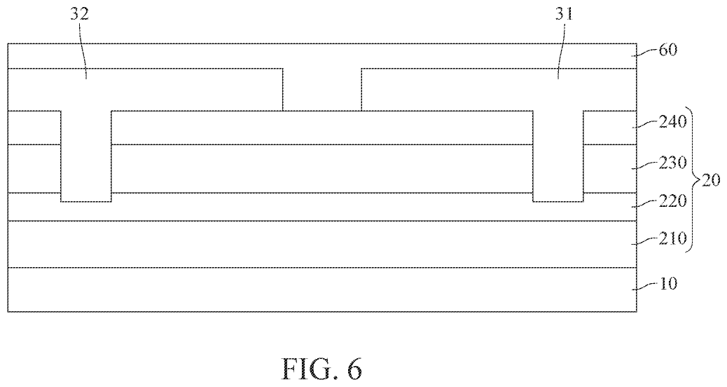

As shown in FIG. 6, the protective layer 60 is formed on the source N type doping part 31, the drain N type doping part 32 and the semiconductor stack 20. In this embodiment, the protective layer 60 may be formed on the source N type doping part 31, the drain N type doping part 32 and the cap layer 240 of the semiconductor stack 20 by atomic layer deposition (ALD). The protective layer 60 may have a thickness of tens of nanometers.

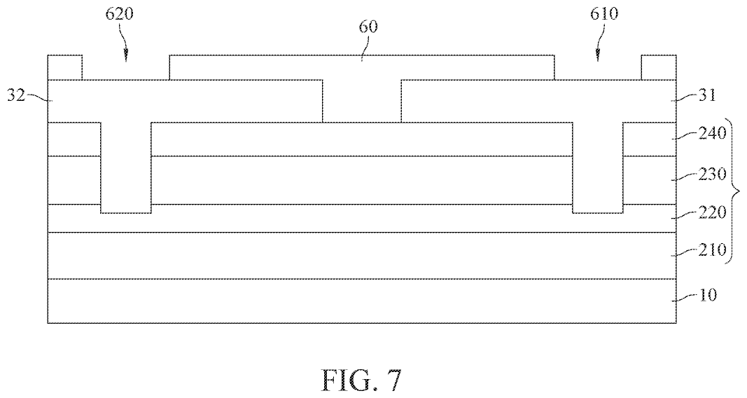

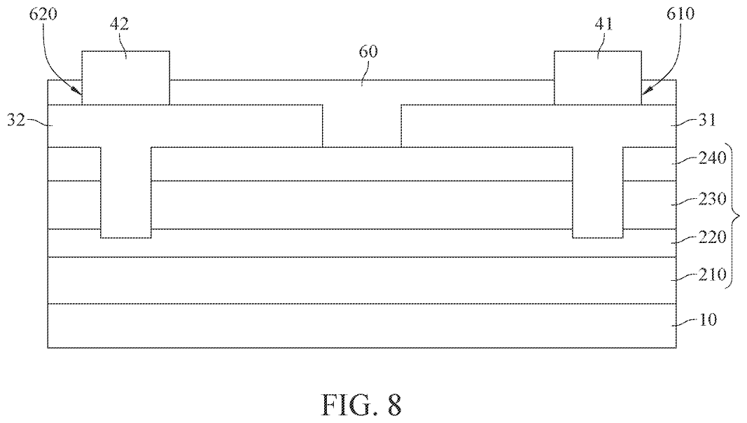

As shown in FIGS. 7 and 8, the source electrode 41 is formed on the source N type doping part 31, and the drain electrode 42 is formed on the drain N type doping part 32. Further, referring to FIG. 7, a first opening 610 and a second opening 620 are formed in the protective layer 60. The first opening 610 exposes the source N type doping part 31, and the second opening 620 exposes the drain N type doping part 32. Next, referring to FIG. 8, the source electrode 41 located in the first opening 610 is formed on the source N type doping part 31, and the drain electrode 42 located in the second opening 620 is formed on the drain N type doping part 32. The source electrode 41 and the drain electrode 42 may protrude out of the protective layer 60, or may be flush with a top surface of the protective layer 60. In this embodiment, the first opening 610 and the second opening 620 may be formed by removing a part of the protective layer 60 by a dry etching process, and the source electrode 41 and the drain electrode 42 may be formed by sputtering, physical vapor deposition (PVD) or chemical vapor deposition (CVD).

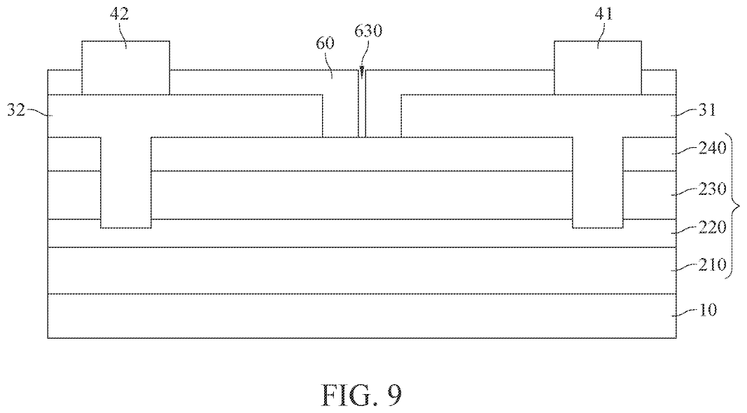

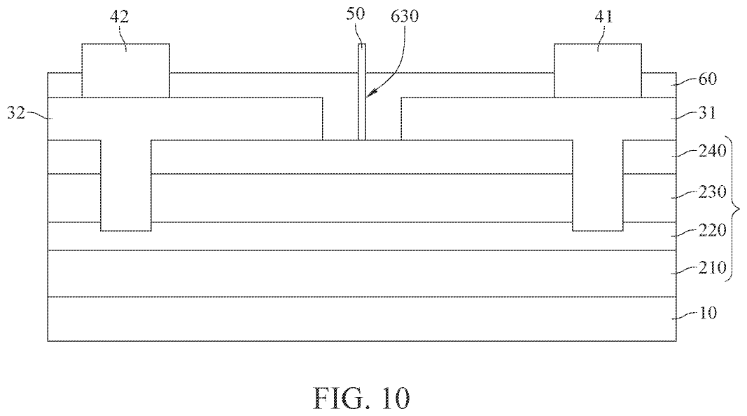

As shown in FIGS. 9 and 10, the gate electrode 50 located between the source N type doping part 31 and the drain N type doping part 32 is formed on the semiconductor stack 20. Further, referring to FIG. 9, a third opening 630 exposing the cap layer 240 of the semiconductor stack 20 may be formed in the protective layer 60 by atomic layer etching (ALE). The third opening 630 may have a width of tens of nanometers. Then, referring to FIG. 10, a gate electrode 50 is formed in the third opening 630.

After the gate electrode 50 is formed, the protective layer 60 may be selectively thinned to entirely expose the source electrode 41 and the drain electrode 42.

According to this embodiment, the source N type doping part 31 and the drain N type doping part 32 are formed by patterning the N type doping layer 30 by electron beam lithography. Thus, comparing to conventional fabrication method, additional silicon oxide layer or silicon nitride layer is not required to be formed between the N type doping layer 30 and the semiconductor stack 20 as a mask used in the epitaxial process for forming the N type doping layer 30, and thus the step of removing the silicon oxide layer or silicon nitride layer by an etching liquid can be omitted. In this way, the semiconductor stack 20 is prevented from being damage by the etching liquid, thereby ensuring the excellent performance of the semiconductor device 1A. In addition, the patterning performed by electron beam lithography shortens the gap width d between the source N type doping part 31 and the drain N type doping part 32, thereby reducing the resistance of a path extending from the source electrode 41 to the drain electrode 42 through the semiconductor layer (e.g., through the channel layer 220 and the N type doping layer 30).

According to this embodiment, the protective layer 60 is formed by atomic layer deposition, which allows the protective layer 60 having thin thickness and low parasitic capacitance to be obtained. The gate electrode 50 is formed by atomic layer etching, which allows the gate electrode 50 having high aspect ratio (e.g., at least 30:1) to be obtained. Moreover, the adoption of the atomic layer etching facilitates the formation of the gate electrode 50 having very small gate length, thereby meeting the requirement of high-frequency application by increasing the cutoff frequency of the semiconductor device 1A.

Furthermore, comparing to conventional fabrication method that performs an annealing step on the source electrode and the drain electrode under a temperature of, for example, at least 800° C., this embodiment provides the source N type doping part 31 and the drain N type doping part 32 that are in contact with the channel layer 220. Thus, in this embodiment, the annealing step for the source electrode 41 and the drain electrode 42 is allowed to be omitted, thereby preventing the annealing from causing the surfaces of the source electrode 41 and the drain electrode 42 to be rough.

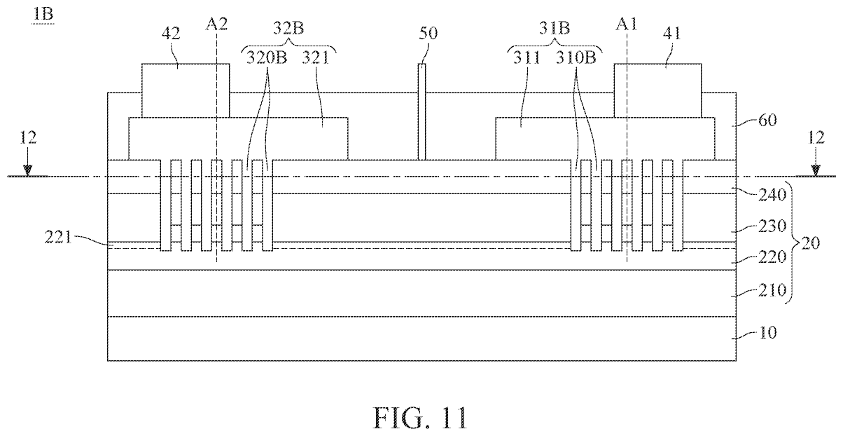

In FIG. 1, the source N type doping part 31 includes one leg part 310 and the drain N type doping part 32 includes one leg part 320, but the disclosure is not limited thereto. Please refer to FIG. 11 that is a schematic view of a semiconductor device 1B according to a second embodiment of the disclosure. In this embodiment, the semiconductor device 1B includes the substrate 10, the semiconductor stack 20, a source N type doping part 31B, a drain N type doping part 32B, the source electrode 41, the drain electrode 42 and the gate electrode 50. The semiconductor device 1B and the semiconductor device 1A in FIG. 1 are similar in structure, and thus the difference therebetween will be mainly described hereinafter.

In this embodiment, the source N type doping part 31B includes the head part 311 and a plurality of leg parts 310B, and the drain N type doping part 32B includes the head part 321 and a plurality of leg parts 320B. The leg parts 310B and 320B extend from the cap layer 240 of the semiconductor stack 20 to the channel layer 220. The leg parts 310B and 320B may not penetrate through the channel layer 220, but may penetrate through the 2D electron gases 221. The multiple leg parts 310B and 320B increase the contact area between the source N type doping part 31B and the channel layer 220 and that between the drain N type doping part 32B and the channel layer 220, thereby decreasing the on-resistance. In some embodiments, multiple leg parts 310B and 320B also increase the contact area between the source N type doping part 31B and the barrier layer 230 or that between the source N type doping part 31B and the cap layer 240, and increase the contact area between the drain N type doping part 32B and the barrier layer 230 or that between the drain N type doping part 32B and the cap layer 240.

As shown in FIG. 11, the central axis (not shown) of the head part 311 of the source N type doping part 31B is located closer to the gate electrode 50 than the central axis A1 of an entire of the plurality of leg parts 310B. Additionally, the central axis (not shown) of the head part 321 of the drain N type doping part 32B is located closer to the gate electrode 50 than the central axis A2 of an entire of the plurality of leg parts 320B.

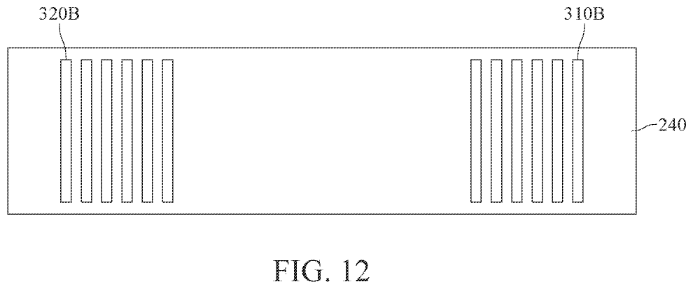

In this embodiment, the leg parts 310B are spaced apart from one another and arranged under the head part 311, and the leg parts 320B are spaced apart from one another and arranged under the head part 321. Please refer to FIG. 12 that is a cross-sectional view of the semiconductor device in FIG. 11 taken along line 12-12. The cross section of each of the leg parts 310B and 320B is in, but not limited to, a rectangular shape shown in FIG. 12.

The leg parts 310B and 320B may be formed by, for example, forming multiple source cavities 201 as shown in FIG. 3 and multiple drain cavities 202 as shown in FIG. 3 in the semiconductor stack 20.

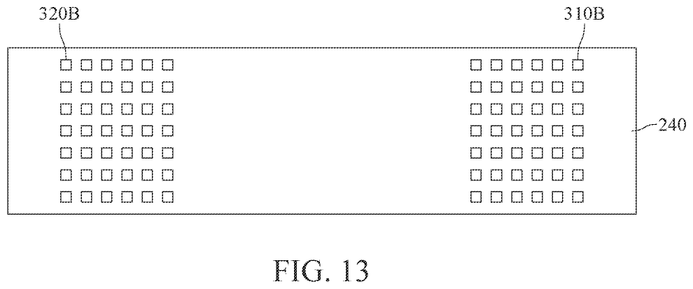

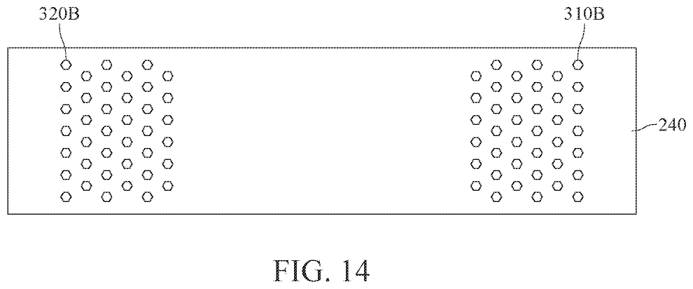

The arrangement of the leg parts 310B and 320B is not limited to that in FIG. 12. FIG. 13 is a cross-sectional view of a semiconductor device according to another embodiment of the disclosure. In FIG. 13, the leg parts 310B may be arranged in an array, and the leg parts 320B may also be arranged in an array. FIG. 14 is a cross-sectional view of a semiconductor device according to still another embodiment of the disclosure. In FIG. 14, the leg parts 310B have a honeycomb arrangement, and the leg parts 320B may also have a honeycomb arrangement. The cross-section of each of the leg parts 310B and 320B is not limited to the square shape shown in FIG. 13 and the hexagonal shape shown in FIG. 14.

As discussed above, according to the semiconductor device and the fabrication method thereof, the source N type doping part and the drain N type doping part are formed by patterning the N type doping layer by electron beam lithography. Thus, comparing to conventional fabrication method, additional silicon oxide layer or silicon nitride layer is not required to be formed between the N type doping layer and the semiconductor stack as a mask used in the epitaxial process for forming the N type doping layer, and thus the step of removing the silicon oxide layer or silicon nitride layer by an etching liquid can be omitted. In this way, the semiconductor stack is prevented from being damage by the etching liquid, thereby ensuring the excellent performance of the semiconductor device. In addition, the patterning performed by electron beam lithography shortens the gap width between the source N type doping part and the drain N type doping part, thereby reducing the resistance of a path extending from the source electrode to the drain electrode through the semiconductor layer.

In addition, in some embodiments, the protective layer is formed by atomic layer deposition, which allows the protective layer having thin thickness and low parasitic capacitance to be obtained. The gate electrode is formed by atomic layer etching, which allows the gate electrode having high aspect ratio to be obtained. Moreover, the adoption of the atomic layer etching facilitates the formation of the gate electrode having very small gate length, thereby meeting the requirement of high-frequency application by increasing the cutoff frequency of the semiconductor device.

Furthermore, comparing to conventional fabrication method that performs an annealing step on the source electrode and the drain electrode, this embodiment provides the source N type doping part and the drain N type doping part that are in contact with the channel layer. Thus, the annealing step for the source electrode and the drain electrode is allowed to be omitted, thereby preventing the annealing from causing the surfaces of the source electrode and the drain electrode to be rough.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A fabrication method of a semiconductor device, comprising:
forming a semiconductor stack on a substrate;
forming a N type doping layer on the semiconductor stack;
patterning the N type doping layer by electron beam lithography to form a source N type doping part and a drain N type doping part;
forming a source electrode on the source N type doping part;
forming a drain electrode on the drain N type doping part; and
forming a gate electrode that is located between the source N type doping part and the drain N type doping part on the semiconductor stack.

2. The fabrication method of a semiconductor device according to claim 1, wherein the semiconductor stack comprises a buffer layer, a channel layer, a barrier layer and a cap layer that are sequentially stacked, and the channel layer is in contact with the barrier layer on a heterojunction.

3. The fabrication method of a semiconductor device according to claim 2, wherein the channel layer and the cap layer comprises gallium nitride, and the barrier layer comprises at least one of AlN, AlGaN and InAlN.

4. The fabrication method of a semiconductor device according to claim 2, wherein forming the N type doping layer on the semiconductor stack comprises:
forming at least one source cavity and at least one drain cavity in the semiconductor stack, wherein the at least one source cavity and the at least one drain cavity penetrate through the barrier layer and the cap layer without penetrating through the channel layer; and
forming the N type doping layer in the at least one source cavity, in the at least one drain cavity and on the cap layer.

5. The fabrication method of a semiconductor device according to claim 4, wherein the at least one source cavity comprises a plurality of source cavities and the at least one drain cavity comprises a plurality of drain cavities.

6. The fabrication method of a semiconductor device according to claim 1, further comprising:
forming a protective layer on the source N type doping part, the drain N type doping part and the semiconductor stack;
wherein, forming the source electrode on the source N type doping part comprises forming the source electrode in a first opening of the protective layer exposing the source N type doping part;
wherein, forming the drain electrode on the drain N type doping part comprises forming the drain electrode in a second opening of the protective layer exposing the drain N type doping part; and
wherein, forming the gate electrode on the semiconductor stack comprises forming the gate electrode in a third opening of the protective layer exposing the semiconductor stack.

7. The fabrication method of a semiconductor device according to claim 6, wherein the protective layer is formed on the source N type doping part, the drain N type doping part and the semiconductor stack by atomic layer deposition.

8. The fabrication method of a semiconductor device according to claim 6, wherein the third opening of the protective layer is formed by atomic layer etching.

9. The fabrication method of a semiconductor device according to claim 1, wherein the N type doping layer is a N type GaN doping layer.

10. The fabrication method of a semiconductor device according to claim 1, wherein a gap width between the source N type doping part and the drain N type doping part is at least ten times larger than a width of the gate electrode.

11. A semiconductor device, comprising:
a substrate;
a semiconductor stack, formed on the substrate;
a source N type doping part, formed on the semiconductor stack;
a drain N type doping part, formed on the semiconductor stack;
a source electrode, formed on the source N type doping part;
a drain electrode, formed on the drain N type doping part; and
a gate electrode, formed on the semiconductor stack and located between the source N type doping part and the drain N type doping part;
wherein, a gap width between the source N type doping part and the drain N type doping part is at least ten times larger than a width of the gate electrode.

12. The semiconductor device according to claim 11, wherein the semiconductor stack comprises a buffer layer, a channel layer, a barrier layer and a cap layer, and the channel layer is in contact with the barrier layer on a heterojunction.

13. The semiconductor device according to claim 12, wherein the channel layer and the cap layer comprises GaN, and the barrier layer comprises at least one of AlN, AlGaN and InAlN.

14. The semiconductor device according to claim 12, wherein the source N type doping part and the drain N type doping part each comprise a plurality of leg parts extending from the cap layer to the channel layer without penetrating through the channel layer.

15. The semiconductor device according to claim 11, wherein the source N type doping part and the drain N type doping part each comprise a head part and at least one leg part, and a central axis of the head part is located closer to the gate electrode than a central axis of the at least one leg part.

16. The semiconductor device according to claim 11, further comprising a protective layer formed on the semiconductor stack, wherein the protective layer covers the source N type doping part and the drain N type doping part, and the source electrode and the drain electrode protrude out of the protective layer.

17. The semiconductor device according to claim 11, wherein the gap width between the source N type doping part and the drain N type doping part ranges from 100.0 nm to 200.0 nm, and the width of the gate electrode ranges from 10.0 nm to 20.0 nm.

18. The semiconductor device according to claim 11, wherein the source N type doping part and the drain N type doping part are doped with N type GaN.
